(19) United States
(12) Patent Application Publication
(10) Pub. No.: US 2025/0261522 A1
(43) Pub. Date: Aug. 14, 2025

(54) DISPLAY PANEL

(71) Applicant: SAMSUNG DISPLAY CO., LTD., Yongin-si (KR)

(72) Inventor: Cheolhwan EOM, Yongin-si (KR)

(21) Appl. No.: 18/438,905

(22) Filed: Feb. 12, 2024

(30) Foreign Application Priority Data
Mar. 24, 2023 (KR) 10-2023-0039032
Jun. 22, 2023 (KR) 10-2023-0080634

(51) Int. Cl. H10K 59/124

(52) U.S. Cl. CPC H10K 59/124

(57) ABSTRACT

A display panel includes a substrate including a display area and an intermediate area, where the display area surrounds a through hole of the display panel and the intermediate area is between the through hole and the display area, an organic insulating layer disposed over the substrate and defining a groove in the intermediate area, a first metal layer disposed under the organic insulating layer, a second metal layer disposed between the first metal layer and the organic insulating layer and overlapping the first metal layer and the groove, and a third metal layer disposed over the organic insulating layer and including a tip protruding from a side surface of the groove to a center of the groove.

This application claims priority to Korean Patent Application No. 10-2023-0039032, filed on Mar. 24, 2023, and Korean Patent Application No. 10-2023-0080634, filed on Jun. 22, 2023, and all the benefits accruing therefrom under 35 U.S.C. § 119, the contents of which in their entireties are herein incorporated by reference.

### BACKGROUND

### 1. Field

One or more embodiments relate to a display panel including an opening area inside a display area.

### 2. Description of the Related Art

Recently, display apparatuses have been used for various purposes. Also, as display apparatuses have become thinner and lighter, display apparatuses are used in various fields.

As various functions combined or associated with a display apparatus have been added, the area occupied by a display area in the display apparatus has increased. To add various functions to a display apparatus while increasing the area of a display area, research has been conducted into a display apparatus in which various components may be arranged in a display area.

### SUMMARY

One or more embodiments include a display panel including an opening area inside a display area, where various types of components may be arranged in the opening area.

Additional aspects will be set forth in part in the description which follows and, in part, will be apparent from the description, or may be learned by practice of embodiments of the disclosure.

According to one or more embodiments, a display panel includes a substrate including a display area and an intermediate area, where the display area surrounds a through hole of the display panel and the intermediate area is between the through hole and the display area, an organic insulating layer disposed over the substrate and defining a groove in the intermediate area, a first metal layer disposed under the organic insulating layer, a second metal layer disposed between the first metal layer and the organic insulating layer and overlapping the first metal layer and the groove, and a third metal layer disposed over the organic insulating layer and including a tip protruding from a side surface of the groove to a center of the groove.

In an embodiment, an end of the tip may overlap the second metal layer in a plan view.

In an embodiment, the display panel may further include an inorganic insulating layer disposed between the first metal layer and the second metal layer, where the organic insulating layer may define a first opening located in the intermediate area and spaced apart from the second metal layer in a plan view, and the third metal layer may directly contact the inorganic insulating layer through the first opening.

In an embodiment, the first opening may overlap the first metal layer in a plan view.

In an embodiment, a width of the second metal layer may be greater than a width of the groove.

In an embodiment, a width of the second metal layer may be less than a width of the groove.

In an embodiment, an upper surface of the second metal layer and at least a portion of a side surface of the second metal layer may be exposed from the organic insulating layer through the groove.

In an embodiment, the groove may include a sub-groove defined by a side surface of the groove, a bottom surface of the groove, and a side surface of the second metal layer.

In an embodiment, the groove may include a first groove and a second groove, a width of the second metal layer corresponding to the first groove may be less than a width of the first groove, and a width of the second metal layer corresponding to the second groove may be greater than a width of the second groove.

In an embodiment, the display panel may further include a light emitting diode disposed in the display area and including a pixel electrode, an opposite electrode, and an intermediate layer disposed between the pixel electrode and the opposite electrode, where the intermediate layer may extend from the display area to the intermediate area and may be disconnected by the groove.

According to one or more embodiments, a display panel includes a substrate including a display area and an intermediate area, where the display area surrounds a through hole and the intermediate area is between the through hole and the display area, an organic insulating layer disposed over the substrate and defining a groove in the intermediate area, a first sub-metal layer disposed under the organic insulating layer, overlapping the groove, and spaced apart from a center of the groove, a second sub-metal layer disposed between the first sub-metal layer and the organic insulating layer, overlapping the groove and the first sub-metal layer, and spaced apart from the center of the groove in a plan view, and a third metal layer disposed over the organic insulating layer and including a tip protruding from a side surface of the groove to the center direction of the groove, where an end of the tip overlaps the second sub-metal layer in the plan view.

In an embodiment, the organic insulating layer may define a first opening located in the intermediate area and overlapping the second sub-metal layer, and the third metal layer may directly contact the second sub-metal layer through the first opening.

In an embodiment, the second sub-metal layer may define a sub-opening between the groove and the first opening in the plan view, and the sub-opening may separate the second sub-metal layer into a first portion and a second portion.

In an embodiment, the first portion of the second sub-metal layer may overlap the first opening in the plan view, and the second portion of the second sub-metal layer may overlap the groove in the plan view.

In an embodiment, the display panel may further include a third sub-metal layer disposed in a same layer as the first sub-metal layer and apart from the first sub-metal layer with the center of the groove therebetween, and a fourth sub-metal layer disposed in a same layer as the second sub-metal layer and apart from the second sub-metal layer with the center of the groove therebetween.

In an embodiment, a spacing distance between the second sub-metal layer and the fourth sub-metal layer may be less than a width of the groove.

In an embodiment, an upper surface of the second sub-metal layer and at least a portion of a side surface of the second sub-metal layer may be exposed from the organic insulating layer through the groove.

In an embodiment, the display panel may further include a light emitting diode disposed in the display area and including a pixel electrode, an opposite electrode, and an intermediate layer disposed between the pixel electrode and the opposite electrode, where the intermediate layer may extend from the display area to the intermediate area and may be disconnected by the groove.

According to one or more embodiments, a display panel includes a substrate including a display area surrounding a through hole of the display panel and an intermediate area between the through hole and the display area, an organic insulating layer disposed over the substrate and defining a first groove and a second groove located in the intermediate area, a first metal layer disposed under the organic insulating layer and overlapping the first groove, a first sub-metal layer disposed under the organic insulating layer, overlapping the second groove, and spaced apart from a center of the second groove in a plan view, a second metal layer disposed between the first metal layer and the organic insulating layer and overlapping the first metal layer and the first groove, a second sub-metal layer disposed between the first sub-metal layer and the organic insulating layer, overlapping the first sub-metal layer, and spaced apart from the center of the second groove in the plan view, a third metal layer disposed over the organic insulating layer and including a first tip protruding from a side surface of the first groove to a center of the first groove, and a fourth metal layer disposed over the organic insulating layer and including a second tip protruding from a side surface of the second groove to the center of the second groove.

In an embodiment, an end of the first tip may overlap the second metal layer in the plan view, and an end of the second tip may overlap the second sub-metal layer in the plan view.

Other aspects, features, and advantages other than those described above will become apparent from the accompanying drawings, the appended claims, and the detailed description of the disclosure.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view schematically illustrating an electronic apparatus according to an embodiment;

FIG. 2 is a cross-sectional view briefly illustrating an electronic apparatus according to an embodiment;

FIG. 3 is a plan view schematically illustrating a display panel according to an embodiment;

FIG. 4 is an equivalent circuit diagram schematically illustrating a pixel included in a display panel according to an embodiment;

FIG. 5 is a plan view schematically illustrating a portion of a display panel according to an embodiment;

FIG. 6 is a cross-sectional view schematically illustrating a display panel according to an embodiment;

FIGS. 7A and 7B are cross-sectional views schematically illustrating a groove in a display panel according to embodiments;

FIGS. 8A and 8B are plan views schematically illustrating a portion of a display panel according to embodiments;

FIGS. 9A to 9D are cross-sectional views schematically illustrating cross-sections of a display panel during a manufacturing process according to an embodiment;

FIG. 10 is a cross-sectional view schematically illustrating a display panel according to an embodiment;

FIG. 11 is a cross-sectional view schematically illustrating a groove in a display panel according to an embodiment;

FIG. 12 is a plan view schematically illustrating a portion of a display panel according to an embodiment;

FIG. 13 is a cross-sectional view schematically illustrating a groove in a display panel according to an embodiment;

FIG. 14 is a plan view schematically illustrating a portion of a display panel according to an embodiment; and

FIG. 15 is a cross-sectional view schematically illustrating a display panel according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

The disclosure may include various embodiments and modifications, and certain embodiments thereof are illustrated in the drawings and will be described herein in detail. The features of the disclosure and the accomplishing methods thereof will become apparent from the embodiments described below in detail with reference to the accompanying drawings. However, the disclosure is not limited to the embodiments described below, and may be embodied in various modes.

Hereinafter, embodiments will be described in detail with reference to the accompanying drawings, and in the following description, like reference numerals will denote like elements and redundant descriptions thereof will be omitted.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. As used herein, “A and/or B” represents the case of A, B, or A and B. Also, “at least one of A and B” represents the case of A, B, or A and B. Throughout the disclosure, the expression “at least one of a, b or c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or component is referred to as being “on” another layer, region, or component, it may be “directly on” the other layer, region, or component or may be “indirectly on” the other layer, region, or component with one or more intervening layers, regions, or components therebetween.

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, or component is referred to as being “electrically connected to” another layer, region, or component, it may be “directly electrically connected to” the other layer, region, or component and/or may be “indirectly electrically connected to” the other layer, region, or component with one or more intervening layers, regions, or components therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

As used herein, the x axis, the y axis, and the z axis are not limited to three axes of the rectangular coordinate system, and may be interpreted in a broader sense. For example, the x-axis, y-axis, and z-axis may be perpendicular to each other or may refer to different directions that are not perpendicular to each other.

When a certain embodiment may be implemented differently, a particular process order may be performed differently from the described order. For example, two processes described in succession may be performed substantially at the same time or may be performed in an order opposite to the described order.

Sizes of elements in the drawings may be exaggerated for convenience of description. In other words, because the sizes and shapes of components in the drawings are arbitrarily illustrated for convenience of description, the disclosure is not limited thereto.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

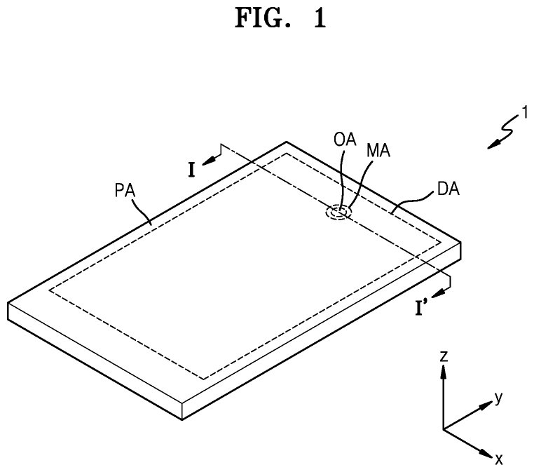

FIG. 1 is a perspective view schematically illustrating an electronic apparatus according to an embodiment.

Referring to FIG. 1, an embodiment of an electronic apparatus 1 may be a display apparatus capable of displaying a moving image or a still image and may be used (or implemented) as a display screen of various products such as televisions, notebook computers, monitors, billboards, and Internet of Things (IoT) as well as portable electronic apparatuses such as mobile phones, smart phones, tablet personal computers (PCs), mobile communication terminals, electronic notebooks, electronic books, portable multimedia players (PMPs), navigation, and Ultra Mobile PCs (UMPCs). Also, the electronic apparatus 1 according to an embodiment may be used in wearable devices such as smart watches, watch phones, glasses-type displays, and head-mounted displays (HMDs). Also, the electronic apparatus 1 according to an embodiment may be used as a center information display (CID) arranged in a vehicle's instrument panel or a vehicle's center fascia or dashboard, a room mirror display replacing a vehicle's side mirror, or a display arranged at a rear side of a vehicle's front seat as an entertainment for a vehicle's rear seat. FIG. 1 illustrates that an embodiment where the electronic apparatus 1 is used as a smart phone.

In an embodiment, the electronic apparatus 1 may be formed in a rectangular shape in a plan view. For example, the electronic apparatus 1 may have a rectangular planar shape having a short side in an x direction and a long side in an y direction as illustrated in FIG. 1. In FIG. 1, a z direction may be a thickness direction of the electronic apparatus 1. An edge where the short side in the x direction and the long side in the y direction meet each other may be formed in a round shape having a certain curvature or may be formed in a right-angle shape. The planar shape of the electronic apparatus 1 is not limited to a rectangular shape and may be any other polygonal shape, an elliptical shape, or an irregular shape.

The electronic apparatus 1 may include an opening area OA and a display area DA surrounding at least a portion of the opening area OA. The electronic apparatus 1 may include an intermediate area MA located between the opening area OA and the display area DA, and a peripheral area PA outside the display area DA, for example, around the display area DA. The intermediate area MA may have a closed-loop shape entirely surrounding the opening area OA in a plan view or when viewed in the z direction.

The opening area OA may be located inside the display area DA. In an embodiment, the opening area OA may be arranged at the upper center of the display area DA as illustrated in FIG. 1. Alternatively, the opening area OA may be variously arranged such as being arranged at the upper left of the display area DA or arranged at the upper right of the display area DA. FIG. 1 illustrates an embodiment where a single opening area OA is provided. However, in an alternative embodiment, a plurality of opening areas OA may be provided.

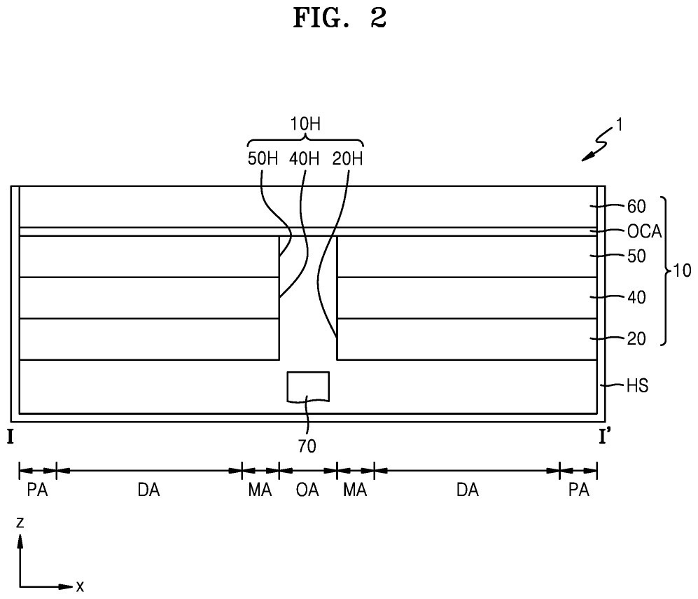

FIG. 2 is a cross-sectional view briefly illustrating an electronic apparatus according to an embodiment.

Referring to FIG. 2, an embodiment of the electronic apparatus 1 may include a display panel 10 and a component 70 arranged in an opening area OA of the display panel 10. The display panel 10 and the component 70 may be accommodated in a housing HS.

The display panel 10 may include an image generating layer 20, an input sensing layer 40, an optical functional layer 50, and a cover window 60.

The image generating layer 20 may include display elements (or light emitting elements) that emit light to display an image. In an embodiment, the display element may include a light emitting diode, for example, an organic light emitting diode including an organic emission layer. In an embodiment, the light emitting diode may be an inorganic light emitting diode including an inorganic material. The inorganic light emitting diode may include a PN diode including inorganic semiconductor-based materials. When a voltage is applied to the PN junction diode in a forward direction, holes and electrons may be injected thereinto and energy generated by recombination of the holes and electrons may be converted into light energy to emit light of a certain color. The inorganic light emitting diode described above may have a width of several to several hundred micrometers or several to several hundred nanometers. In some embodiments, the image generating layer 20 may include a quantum dot light emitting diode. For example, an emission layer of the image generating layer 20 may include an organic material, may include an inorganic material, may include quantum dots, may include an organic material and quantum dots, or may include an inorganic material and quantum dots.

The input sensing layer 40 may be configured to obtain coordinate information corresponding to an external input, for example, a touch event. The input sensing layer 40 may include a sensing electrode (or a touch electrode) and signal lines (trace lines) connected to the sensing electrode. The input sensing layer 40 may be disposed over the image generating layer 20. The input sensing layer 40 may be configured to sense an external input based on a mutual capacitance method and/or a self capacitance method.

The input sensing layer 40 may be directly formed over the image generating layer 20 or may be separately formed and then coupled thereto through an adhesive layer such as an optical clear adhesive. In an embodiment, for example, the input sensing layer 40 may be continuously formed after the process of forming the image generating layer 20, and in such an embodiment, an adhesive layer may not be arranged between the input sensing layer 40 and the image generating layer 20. FIG. 2 illustrates an embodiment where the input sensing layer 40 is arranged between the image generating layer 20 and the optical functional layer 50; however, in an alternative embodiment, the input sensing layer 40 may be disposed over the optical functional layer 50.

The optical functional layer 50 may include an anti-reflection layer. The anti-reflection layer may be configured to reduce the reflectance of light (external light) incident from the outside through the cover window 60 toward the display panel 10. In an embodiment, the anti-reflection layer may include a phase retarder and a polarizer. In an alternative embodiment, the anti-reflection layer may include a black matrix and color filters. The color filters may be arranged by considering the color of light emitted from each of the light emitting diodes of the image generating layer 20.

In an embodiment, the display panel 10 may include a panel hole 10H (or an opening) defined or formed through some of the layers constituting the display panel 10 to improve the transmittance of the opening area OA. The panel hole 10H may include first, second, and third holes 20H, 40H, and 50H respectively defined through the image generating layer 20, the input sensing layer 40, and the optical functional layer 50. The first hole 20H of the image generating layer 20, the second hole 40H of the input sensing layer 40, and the third hole 50H of the optical functional layer 50 may overlap each other to form the panel hole 10H in the display panel 10.

The cover window 60 may be disposed over the optical functional layer 50. The cover window 60 may be coupled to the optical functional layer 50 through an adhesive layer such as an optical clear adhesive OCA arranged therebetween. The cover window 60 may cover the first hole 20H of the image generating layer 20, the second hole 40H of the input sensing layer 40, and the third hole 50H of the optical functional layer 50.

The cover window 60 may include a glass material or a plastic material. The glass material may include ultra-thin glass. The plastic material may include polyether sulfone, polyacrylate, polyether imide, polyethylene naphthalate, polyethylene terephthalate, polyphenylene sulfide, polyarylate, polyimide, polycarbonate, or cellulose acetate propionate.

The opening area OA may be a type of component area (e.g., a sensor area, a camera area, or a speaker area) in which the component 70 for adding various functions to the electronic apparatus 1 is located.

The component 70 may include an electronic element. For example, the component 70 may include an electronic element using light or sound. For example, the electronic element may include a sensor such as an infrared sensor using light, a camera for receiving light to obtain an image, a sensor for outputting and sensing light or sound to measure a distance or recognize a fingerprint or the like, a miniature lamp for outputting light, or a speaker for outputting sound. In an embodiment of an electronic element using light, the electronic element may use light of various wavelength bands such as visible light, infrared light, and ultraviolet light. The opening area OA may correspond to an area through which light and/or sound output from the component 70 to the outside or propagating from the outside toward the electronic element may be transmitted.

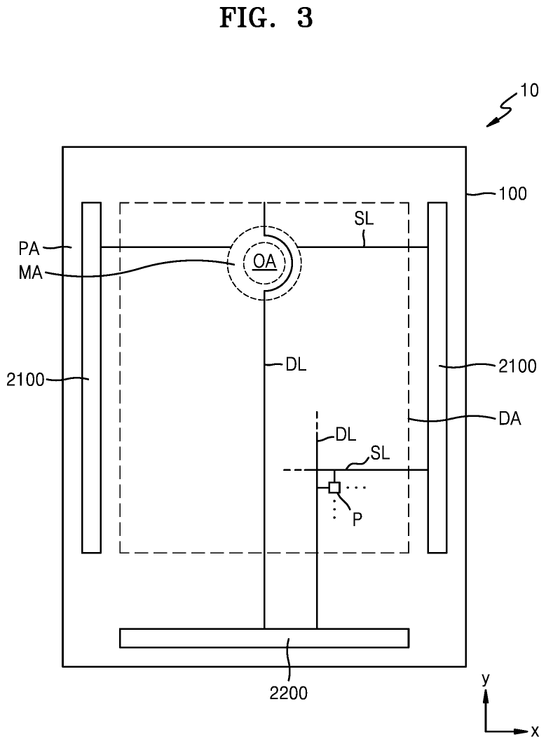

FIG. 3 is a plan view schematically illustrating a display panel according to an embodiment.

Referring to FIG. 3, an embodiment of the display panel 10 may include an opening area OA, a display area DA, an intermediate area MA, and a peripheral area PA.

The display panel 10 may include a plurality of pixels P arranged in the display area DA, and the display panel 10 may display an image by using light emitted from each pixel P. Each pixel P may emit red, green, or blue light by using a light emitting diode. The light emitting diode of each pixel P may be electrically connected to a scan line SL and a data line DL.

A scan driver 2100 for providing a scan signal to each pixel P, a data driver 2200 for providing a data signal to each pixel P, and a first main power line (not illustrated) and a second main power line (not illustrated) for respectively providing a first power voltage and a second power voltage may be arranged in the peripheral area PA. In an embodiment, the scan driver 2100 may be arranged on each of opposing sides with the display area DA therebetween. In such an embodiment, the pixel P arranged on the left side of the opening area OA may be connected to the scan driver 2100 arranged on the left side, and the pixel P arranged on the right side of the opening area OA may be connected to the scan driver 2100 arranged on the right side.

The intermediate area MA may surround the opening area OA. The intermediate area MA may be an area in which a display element such as a light emitting diode for emitting light is not arranged, and signal lines for providing signals to pixels P arranged around the opening area OA may pass through the intermediate area MA. For example, data lines DL and/or scan lines SL may intersect the display area DA, and some portions of the data lines DL and/or the scan lines SL may bypass the intermediate area MA along the edge of the panel hole 10H (see FIG. 2) of the display panel 10 formed in the opening area OA. In an embodiment, as shown in FIG. 3, the data lines DL intersect the display area DA in the y direction and some data lines DL bypass and partially surround the opening area OA in the intermediate area MA. In such an embodiment, the scan lines SL may intersect the display area DA in the x direction and may be spaced apart from each other with the opening area OA therebetween.

FIG. 3 illustrates an embodiment where the data driver 2200 is arranged adjacent to one side of a substrate 100; however, in an alternative embodiment, the data driver 2200 may be disposed over a printed circuit board electrically connected to a pad arranged on one side of the display panel 10. The printed circuit board may be flexible, and a portion of the printed circuit board may be bent to be located under the rear surface of the substrate 100.

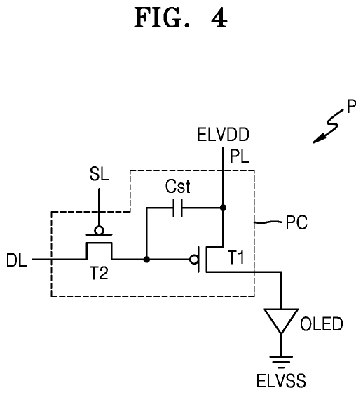

FIG. 4 is an equivalent circuit diagram schematically illustrating a pixel included in a display panel according to an embodiment.

Referring to FIG. 4, an embodiment of the pixel P may include a pixel circuit PC and an organic light emitting diode OLED as a display element connected to the pixel circuit PC.

The pixel circuit PC may include a first transistor T1, a second transistor T2, and a storage capacitor Cst. Each pixel P may emit, for example, red, green, blue, or white light from the organic light emitting diode OLED.

As a driving thin film transistor, the first transistor T1 may be connected to a driving voltage line PL and the storage capacitor Cst and may be configured to control a driving current flowing from the driving voltage line PL through the organic light emitting diode OLED in response to a voltage value stored in the storage capacitor Cst.

As a switching thin film transistor, the second transistor T2 may be connected to a scan line SL and a data line DL and may be configured to transmit a data voltage input from the data line DL to the first transistor T1, based on a switching voltage input from the scan line SL. The storage capacitor Cst may be connected to the second transistor T2 and the driving voltage line PL and may be configured to store a voltage corresponding to the difference between a voltage received from the second transistor T2 and a first power voltage ELVDD supplied to the driving voltage line PL.

The organic light emitting diode OLED may emit light with a certain brightness corresponding to the driving current. An opposite electrode (e.g., a cathode) of the organic light emitting diode OLED may be supplied with a second power voltage ELVSS.

FIG. 4 illustrates an embodiment where the pixel circuit PC includes two thin film transistors and one storage capacitor; however, the disclosure is not limited thereto. The number of thin film transistors and the number of storage capacitors may be variously modified according to the design of the pixel circuit PC. In an alternative embodiment, for example, the pixel circuit PC may further include four or more thin film transistors in addition to the two thin film transistors described above.

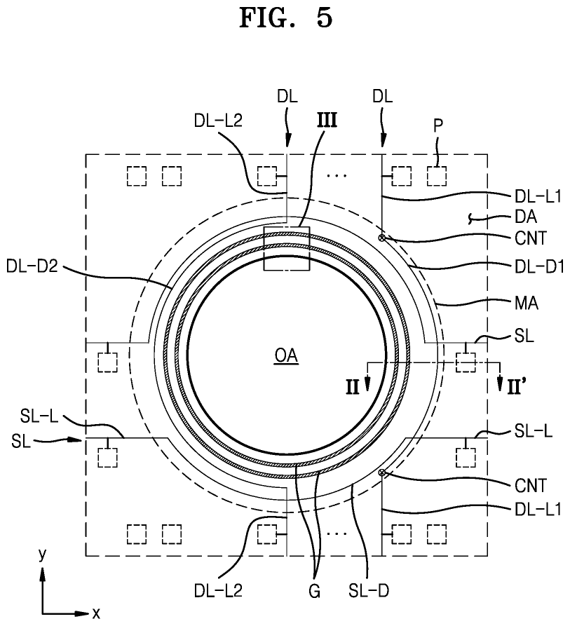

FIG. 5 is a plan view schematically illustrating a portion of a display panel according to an embodiment.

Referring to FIG. 5, in an embodiment of a display panel, pixels P may be arranged apart from each other around the opening area OA. The opening area OA may be defined between the pixels P. For example, as illustrated in FIG. 5, pixels P may be respectively arranged on the upper and lower sides of the opening area OA, and pixels P may be respectively arranged on the left and right sides of the opening area OA. In such an embodiment, the opening area OA may be located inside the display area DA.

Among the signal lines configured to supply signals to the pixels P, signal lines adjacent to the opening area OA may bypass the opening area OA. In the plan view, at least one data line DL among the data lines passing through the display area DA may extend in the y direction to provide data signals to the pixels P respectively disposed over and under the opening area OA and may bypass along the edge of the opening area OA in the intermediate area MA. In the plan view, at least one scan line SL among the scan lines passing through the display area DA may extend in the x direction to provide scan signals to the pixels P respectively arranged on the left and right sides of the opening area OA and may bypass along the edge of the opening area OA in the intermediate area MA.

A bypass (circuitous) portion SL-D of the scan line SL may be located in (or directly on) a same layer as and may be integrally formed with an extension portion SL-L intersecting the display area DA as a single unitary and indivisible part. A bypass portion DL-D1 of at least one data line DL among the data lines DL may be formed in (or directly on) a different layer than an extension portion DL-L1 intersecting the display area DA, and the extension portion DL-L1 and the bypass portion DL-D1 of the data line DL may be connected to each other through a contact hole CNT. A bypass portion DL-D2 of at least one data line DL among the data lines DL may be located in (or directly on) a same layer as and may be integrally formed with an extension portion DL-L2 as a single unitary and indivisible part.

One or more grooves G may be defined or located between the opening area OA and an area of the intermediate area MA bypassed by the scan lines SL and the data lines DL. In the plan view, each of the grooves G may have a ring shape surrounding the opening area OA, and the grooves G may be formed apart from each other. In an embodiment, as shown in FIG. 5, two grooves G are located in the intermediate area MA, and the two grooves G may surround the opening area OA and may have a concentric circle shape having a same center but having different diameters.

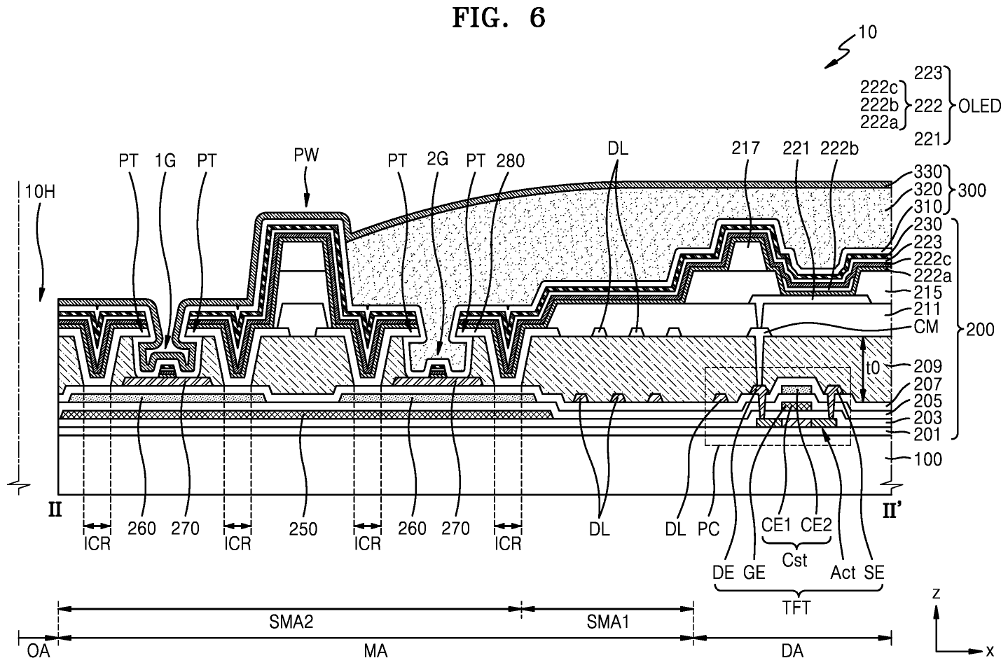

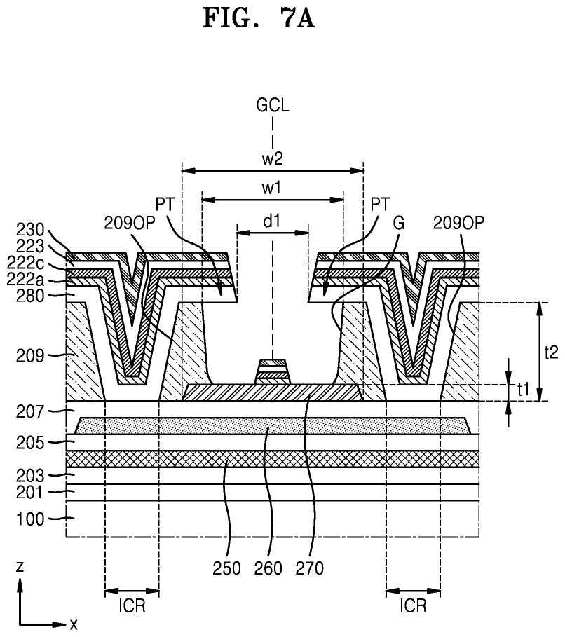

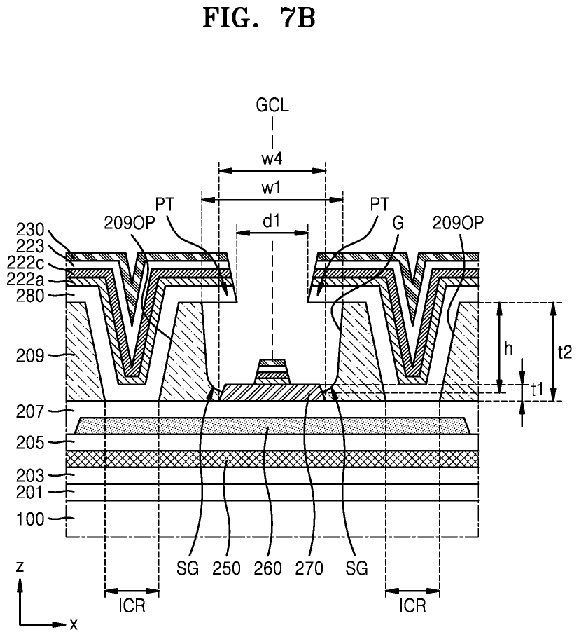

FIG. 6 is a cross-sectional view schematically illustrating a display panel according to an embodiment, and FIGS. 7A and 7B are cross-sectional views schematically illustrating a groove in a display panel according to embodiments. FIG. 6 may correspond to a cross-sectional view taken along line II-II′ of FIG. 5, FIG. 7A is an enlarged view of a groove and an area around the groove illustrated in FIG. 6, and FIG. 7B is a modified embodiment of FIG. 7B.

Referring to FIG. 6, in an embodiment of a display panel, the substrate 100 may include a glass material or a polymer resin. The substrate 100 may include multiple layers, i.e., have a multi-layer structure. For example, the substrate 100 may include a base layer and a barrier layer.

The base layer may include a polymer resin. The polymer resin may include polyethersulfone, polyarylate, polyetherimide, polyethylene naphthalate, polyethylene terephthalate, polyphenylene sulfide, polyimide, polycarbonate, cellulose triacetate, cellulose acetate propionate, or the like.

The barrier layer may be to prevent the penetration of foreign substances and may have a single-layer structure or a multi-layer structure including an inorganic insulating material such as silicon nitride, silicon oxynitride, or silicon oxide.

A buffer layer 201 for preventing impurities from penetrating into a semiconductor layer Act of a thin film transistor TFT may be formed over the substrate 100. The buffer layer 201 may include an inorganic insulating material such as silicon nitride, silicon oxynitride, or silicon oxide and may have a single-layer structure or a multi-layer structure including the above inorganic insulating material.

A pixel circuit PC may be disposed on the buffer layer 201 in the display area DA. The pixel circuit PC may include a thin film transistor TFT and a storage capacitor Cst. Here, the thin film transistor TFT may correspond to the first transistor T1 described above with reference to FIG. 2. The thin film transistor TFT may include a semiconductor layer Act, a gate electrode GE, a source electrode SE, and a drain electrode DE. In some embodiments, at least one selected from the source electrode SE and the drain electrode DE may be omitted and replaced with (or defined by) a conductive area of the semiconductor layer Act.

Although not illustrated in FIG. 6, a data line DL of the pixel circuit PC may be electrically connected to the second transistor T2 (see FIG. 2) included in the pixel circuit PC. FIG. 6 illustrates an embodiment where the thin film transistor TFT is a top gate type thin film transistor in which the gate electrode GE of the thin film transistor TFT is disposed over the semiconductor layer Act with a gate insulating layer 203 therebetween; however, according to some embodiments, the thin film transistor TFT may be a bottom gate type.

The semiconductor layer Act may include polysilicon. Alternatively, the semiconductor layer Act may include amorphous silicon, may include an oxide semiconductor, or may include an organic semiconductor or the like. The gate electrode GE may include a low-resistance metal material. The gate electrode GE may include a conductive material including molybdenum (Mo), aluminum (Al), copper (Cu), titanium (Ti), or the like and may have a single-layer structure or a multi-layer structure including the above material.

The gate insulating layer 203 between the semiconductor layer Act and the gate electrode GE may include an inorganic insulating material such as silicon oxide, silicon nitride, silicon oxynitride, aluminum oxide, titanium oxide, tantalum oxide, or hafnium oxide. The gate insulating layer 203 may have a single-layer structure or a multi-layer structure including the above material.

The storage capacitor Cst may include a lower electrode CE1 and an upper electrode CE2 overlapping each other with a first interlayer insulating layer 205 therebetween. The storage capacitor Cst may overlap the thin film transistor TFT. In an embodiment, as shown in FIG. 6, the gate electrode GE of the thin film transistor TFT is the lower electrode CE1 of the storage capacitor Cst. In an alternative embodiment, the storage capacitor Cst may not overlap the thin film transistor TFT. The storage capacitor Cst may be covered by a second interlayer insulating layer 207. The upper electrode CE2 of the storage capacitor Cst may include a conductive material including molybdenum (Mo), aluminum (Al), copper (Cu), titanium (Ti), or the like and have a single-layer structure or a multi-layer structure including the above material.

The source electrode SE and the drain electrode DE may be disposed on the second interlayer insulating layer 207. The source electrode SE and the drain electrode DE may include a material having high conductivity. The source electrode SE and the drain electrode DE may include a conductive material including molybdenum (Mo), aluminum (Al), copper (Cu), titanium (Ti), or the like and may have a single-layer structure or a multi-layer structure including the above material. For example, the source electrode SE and the drain electrode DE may include a multilayer of Ti/Al/Ti.

The first interlayer insulating layer 205 and the second interlayer insulating layer 207 may include an inorganic insulating material such as silicon oxide, silicon nitride, or silicon oxynitride. The first interlayer insulating layer 205 and the second interlayer insulating layer 207 may have a single-layer structure or a multi-layer structure including the above material.

The pixel circuit PC including the thin film transistor TFT and the storage capacitor Cst may be covered by a first organic insulating layer 209. The first organic insulating layer 209 may include a substantially flat upper surface.

An organic light emitting diode OLED may be disposed on the pixel circuit PC. The organic light emitting diode OLED may include a pixel electrode 221, an opposite electrode 223, and an intermediate layer 222 arranged between the pixel electrode 221 and the opposite electrode 223.

The pixel circuit PC may be electrically connected to the pixel electrode 221 of the organic light emitting diode OLED. For example, as illustrated in FIG. 6, a contact metal layer CM may be arranged between the thin film transistor TFT and the pixel electrode 221. The contact metal layer CM may be connected to the thin film transistor TFT through a contact hole defined or formed in the first organic insulating layer 209, and the pixel electrode 221 may be connected to the contact metal layer CM through a contact hole defined or formed in a second organic insulating layer 211 on the contact metal layer CM. The contact metal layer CM may include a conductive material including molybdenum (Mo), aluminum (Al), copper (Cu), titanium (Ti), or the like and may have a single-layer structure or a multi-layer structure including the above material. In an embodiment, the contact metal layer CM may include a multiple layer of Ti/Al/Ti.

The first organic insulating layer 209 and the second organic insulating layer 211 may include an organic insulating material such as a general-purpose polymer such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or any blend thereof. In an embodiment, the first organic insulating layer 209 and the second organic insulating layer 211 may include polyimide.

The pixel electrode 221 may be disposed on the second organic insulating layer 211. The pixel electrode 221 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In some embodiments, the pixel electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In some embodiments, the pixel electrode 221 may further include a layer formed of ITO, IZO, ZnO, or In₂O₃ over and/or under the above reflective layer.

A pixel definition layer 215 may be disposed on the pixel electrode 221. The pixel definition layer 215 may be provided with an opening exposing the upper surface of the pixel electrode 221 and may cover the edge of the pixel electrode 221. The pixel definition layer 215 may include an organic insulating material. Alternatively, the pixel definition layer 215 may include an inorganic insulating material such as silicon nitride, silicon oxynitride, or silicon oxide. Alternatively, the pixel definition layer 215 may include an organic insulating material and an inorganic insulating material.

The pixel definition layer 215 may be formed in black. The pixel definition layer 215 may include a light blocking material and may be provided in black. The light blocking material may include a resin or paste including carbon black, carbon nanotube, or black dye, metal particles (e.g., nickel (Ni), aluminum (Al), molybdenum (Mo), or any alloy thereof), metal oxide particles (e.g., chromium oxide), or metal nitride particles (e.g., chromium nitride). In an embodiment where the pixel definition layer 215 includes the light blocking material, the reflection of external light by metal structures disposed under the pixel definition layer 215 may be reduced.

The intermediate layer 222 may include an emission layer 222b. The intermediate layer 222 may further include a first functional layer 222a disposed under the emission layer 222b and/or a second functional layer 222c disposed over the emission layer 222b. The emission layer 222b may include a high-molecular or low-molecular weight organic material for emitting light of a certain color.

The first functional layer 222a may have a single-layer structure or a multi-layer structure. In an embodiment, where the first functional layer 222a is formed of a high-molecular weight material, the first functional layer 222a may include a hole transport layer having a single-layer structure and may be formed of poly-(3,4)-ethylene-dihydroxy thiophene or polyaniline. In an embodiment where the first functional layer 222a is formed of a low-molecular weight material, the first functional layer 222a may include a hole injection layer and a hole transport layer.

The second functional layer 222c may have a single-layer structure or a multi-layer structure. The second functional layer 222c may include an electron transport layer and/or an electron injection layer. In some embodiments, the second functional layer 222c may be omitted. In an embodiment where the first functional layer 222a and the emission layer 222b are formed of a high-molecular weight material, the second functional layer 222c may be provided.

The emission layer 222b of the intermediate layer 222 may be arranged for each pixel in the display area DA. The emission layer 222b may be patterned to correspond to the pixel electrode 221. Unlike the emission layer 222b, the first functional layer 222a and/or the second functional layer 222c of the intermediate layer 222 may be commonly formed across several organic light emitting diodes OLED. Also, the first functional layer 222a and/or the second functional layer 222c of the intermediate layer 222 may extend from the display area DA toward the intermediate area MA to be located not only in the display area DA but also in the intermediate area MA.

The opposite electrode 223 may be disposed on the intermediate layer 222. The opposite electrode 223 may include a conductive material having a low work function. For example, the opposite electrode 223 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 223 may further include a layer such as ITO, IZO, ZnO, or In₂O₃ over the (semi) transparent layer including the above material. The opposite electrode 223 may be commonly formed across several organic light emitting diodes OLED. The opposite electrode 223 may extend from the display area DA toward the intermediate area MA to be located not only in the display area DA but also in the intermediate area MA.

In an embodiment, the first functional layer 222a, the second functional layer 222c, and the opposite electrode 223 may be formed by thermal evaporation.

A capping layer 230 may be disposed on the opposite electrode 223. For example, the capping layer 230 may include lithium fluoride (LiF) and may be formed by thermal evaporation. The capping layer 230 may improve the light emission efficiency of the organic light emitting diode OLED according to the principle of constructive interference. The capping layer 230 may be an organic capping layer including an organic material, an inorganic capping layer including an inorganic material, or a composite capping layer including an organic material and an inorganic material. In some embodiments, the capping layer 230 may be omitted.

A spacer 217 may be disposed on the pixel definition layer 215. The spacer 217 may include an organic insulating material such as polyimide. Alternatively, the spacer 217 may include an inorganic insulating material or may include an organic insulating material and an inorganic insulating material.

The spacer 217 may include a different material than the pixel definition layer 215 or may include the same material as the pixel definition layer 215. In an embodiment, the pixel definition layer 215 and the spacer 217 may include polyimide. The pixel definition layer 215 and the spacer 217 may be formed together in a mask process using a halftone mask.

The organic light emitting diode OLED may be covered by a thin film encapsulation layer 300. The thin film encapsulation layer 300 may include at least one organic encapsulation layer and at least one inorganic encapsulation layer. In an embodiment, as shown in FIG. 6, the thin film encapsulation layer 300 includes first and second inorganic encapsulation layers 310 and 330 and an organic encapsulation layer 320 arranged therebetween. In other embodiments, the number of organic encapsulation layers, the number of inorganic encapsulation layers, and the stacking order thereof may be modified.

Each of the first inorganic encapsulation layer 310 and the second inorganic encapsulation layer 330 may include at least one inorganic material selected from aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may have a single-layer structure or a multi-layer structure including the above material. The organic encapsulation layer 320 may include a polymer-based material. The polymer-based material may include acryl-based resin, epoxy-based resin, polyimide, polyethylene, or the like. In an embodiment, the organic encapsulation layer 320 may include acrylate.

The first inorganic encapsulation layer 310 and the second inorganic encapsulation layer 330 may have different thicknesses from each other. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the first inorganic encapsulation layer 310 and the second inorganic encapsulation layer 330 may have a same thickness as each other.

The intermediate area MA may include a first sub-intermediate area SMA1 relatively far from the opening area OA and a second sub-intermediate area SMA2 relatively close to the opening area OA. Lines and grooves G bypassing the opening area OA may be arranged in the intermediate area MA.

Data lines DL may be located in the first sub-intermediate area SMA1. The data lines DL of the first sub-intermediate area SMA1 illustrated in FIG. 6 may correspond to the bypass portions (e.g., DL-D1 and DL-D2) of the data lines DL described above with reference to FIG. 5. The first sub-intermediate area SMA1 may be understood as a line area or a bypass area bypassed by lines such as the data lines DL described above.

The data lines DL may be alternately arranged with an insulating layer therebetween. For example, one of two adjacent data lines DL in the plan view may be disposed under the insulating layer (e.g., the first organic insulating layer 209) and the other thereof may be disposed over the insulating layer (e.g., the first organic insulating layer 209). In such an embodiment where the data lines DL are alternately arranged with an insulating layer therebetween, the distance (pitch) between the data lines may be reduced. FIG. 6 illustrates only the data lines DL located in the first sub-intermediate area SMA1; however, the scan lines SL described above with reference to FIG. 5, for example, the bypass portions of the scan lines SL, may also be located in the first sub-intermediate area SMA1.

One or more grooves G may be arranged in the second sub-intermediate area SMA2. For example, FIG. 6 illustrates an embodiment where a first groove 1G and a second groove 2G are arranged therein. The first groove 1G may be arranged relatively close to the opening area OA, and the second groove 2G may be arranged relatively far from the opening area OA. The organic material layer included in the intermediate layer 222, for example, the first functional layer 222a and/or the second functional layer 222c, may be disconnected (or separated) by the groove G. The second sub-intermediate area SMA2 may be understood as a groove area or a disconnection area (or a separation area) of the organic material layer.

Referring to FIGS. 6 and 7A, the first organic insulating layer 209 may extend from the display area DA to the intermediate area MA. In the second sub-intermediate area SMA2, an inorganic stack may be located between the first organic insulating layer 209 and the substrate 100. The inorganic stack may include a plurality of sub-layers, and the sub-layers may include an inorganic material. For example, the inorganic stack may include at least one inorganic insulating layer and at least one metal layer. For example, in the second sub-intermediate area SMA2, the inorganic stack may include a lower metal layer 250, a first interlayer insulating layer 205, a first metal layer 260, a second interlayer insulating layer 207, and a second metal layer 270. The inorganic stack may be arranged corresponding to each of the grooves 1G and 2G. The lower metal layer 250, the first metal layer 260, and the second metal layer 270 may be arranged to overlap an imaginary center line GCL passing through the center of the groove G. In some embodiments, the lower metal layer 250 may be integrally or commonly provided across a plurality of grooves (e.g., 1G and 2G).

The inorganic stack may adjust the depth of the groove G. For example, in an embodiment where the first organic insulating layer 209 has a maximum thickness to in the thickness direction (z direction) in the display area DA, the first organic insulating layer 209 over the inorganic stack may have a thickness less than the maximum thickness to by leveling of the organic material. As illustrated in FIG. 7A, the second metal layer 270 may have a first thickness t1 in the thickness direction (z direction), and the first organic insulating layer 209 may have a second thickness t2 from the upper surface of the second interlayer insulating layer 207 to the upper surface of the first organic insulating layer 209. The second thickness t2 may be less than the maximum thickness t0 of the first organic insulating layer 209. The depth of the groove G may be a value obtained by subtracting the first thickness t1 from the second thickness t2. In an embodiment, the length of a tip PT described below may be adjusted by adjusting the second thickness t2 and the first thickness t1.

The lower metal layer 250 may be formed in a same process as the lower electrode CE1 of the storage capacitor Cst and the gate electrode GE of the thin film transistor TFT and may include a same material as the lower electrode CE1 and the gate electrode GE. Here, “A and B include a same material” may mean that A and B are deposited in a same process and then separated or spaced apart by patterning or the like and have a same stack structure, layer quality, or the like.

The first metal layer 260 may be formed in a same process as the upper electrode CE2 of the storage capacitor Cst and may include a same material as the upper electrode CE2. The second metal layer 270 may be formed in a same process as the source electrode SE and/or the drain electrode DE of the pixel circuit PC and may include a same material as the source electrode SE and/or the drain electrode DE.

The inorganic insulating layer included in the inorganic stack, for example, the first interlayer insulating layer 205 and the second interlayer insulating layer 207, may include silicon nitride and/or silicon oxide. Compared to silicon oxynitride, silicon nitride and silicon oxide may be relatively resistant to moisture and may be relatively resistant to oxidation even when exposed to moisture.

The groove G may be defined or formed to overlap the second metal layer 270. The groove G may be defined by the first organic insulating layer 209 and the second metal layer 270 overlapping therewith. In other words, the groove G may be defined by the side surface of the first organic insulating layer 209 and the upper surface of the second metal layer 270 exposed from the first organic insulating layer 209. The upper surface of the second metal layer 270 may function as an etch stopper in an etching process of forming the groove G.

In an embodiment, where the groove G has a first width w1 from one side surface to the other side surface thereof, the second metal layer 270 may have a second width w2 greater than the first width w1. That is, the upper surface of the second metal layer 270 may be exposed from the first organic insulating layer 209 by the groove G, but the edge of the second metal layer 270 may be covered by the first organic insulating layer 209.

The first organic insulating layer 209 may define a first opening 209OP arranged apart from the second metal layer 270. In the plan view, the first opening 209OP may overlap the lower metal layer 250 and the first metal layer 260 but may not overlap the second metal layer 270. The first opening 209OP may be defined by the side surface of the first organic insulating layer 209 and the upper surface of the second interlayer insulating layer 207 exposed from the first organic insulating layer 209. A plurality of first openings 209OP may be provided and arranged on opposing sides of each groove G.

A third metal layer 280 may be disposed on the first organic insulating layer 209. The third metal layer 280 may be formed in a same process as the contact metal layer CM and may include a same material as the contact metal layer CM. The third metal layer 280 may extend from the upper surface of the first organic insulating layer 209 and may include a tip PT protruding from the side surface of the first organic insulating layer 209 in the direction of the imaginary center line GCL passing through the center of the groove G. A plurality of third metal layers 280 may be provided and arranged on opposing sides of each groove G. Tips PT arranged facing each other with the groove G therebetween may be spaced apart from each other by a first distance d1. The first distance d1 between the tips PT arranged facing each other may be less than the first width w1 of the groove G. The first distance d1 between the tips PT may be less than the second width w2 of the second metal layer 270. Thus, the end of each of the tips PT may be arranged to overlap the second metal layer 270. The tips PT may form an eaves structure or an undercut structure with the side surface of the groove G.

The third metal layer 280 may directly contact the upper surface of the second interlayer insulating layer 207 through the first opening 209OP. The third metal layer 280 may form an inorganic contact area ICR by directly contacting the second interlayer insulating layer 207. The inorganic contact area ICR may reduce or block a path through which moisture or the like penetrates from the boundary of the panel hole 10H through the first organic insulating layer 209.

The intermediate layer 222 may be disposed on the third metal layer 280. For example, the first functional layer 222a and/or the second functional layer 222c may extend from the display area DA to the intermediate area MA and may be disposed over the third metal layer 280. The first functional layer 222a and/or the second functional layer 222c may be disconnected or separated by the groove G. Likewise, the opposite electrode 223 and the capping layer 230 may also be disconnected or separated by the groove G and the tip PT.

In an alternative embodiment, as illustrated in FIG. 7B, the second metal layer 270 may have a fourth width w4 less than the first width w1 of the groove G. In such an embodiment, at least a portion of the upper surface and side surface of the second metal layer 270 may be exposed from the first organic insulating layer 209 through the groove G. That is, a depth h of the groove G may be greater than a value (t2−t1) obtained by subtracting the first thickness t1 of the second metal layer 270 from the second thickness t2 of the first organic insulating layer 209 over the inorganic stack. In such an embodiment, the first distance d1 between the tips PT may be less than the fourth width w4 of the second metal layer 270. That is, the end of each of the tips PT may be arranged to overlap the second metal layer 270.

The groove G may include sub-grooves SG arranged on opposing sides of the second metal layer 270. The sub-groove SG may be defined by the side surface of the first organic insulating layer 209 and the side surface of the second metal layer 270. The sub-grooves SG may form unevenness on the bottom surface of the groove G to further disconnect or separate the first functional layer 222a and/or the second functional layer 222c. For example, the first functional layer 222a and/or the second functional layer 222c may be deposited in an oblique direction on the substrate 100 during a deposition process and thus may be partially formed not only on the upper surface of the second metal layer 270 but also on the inner surface of the groove G, that is, on the side surface of the first organic insulating layer 209. The sub-grooves SG may further separate or disconnect the first functional layer 222a and/or the second functional layer 222c extending from the upper surface of the second metal layer 270 to the side surface of the first organic insulating layer 209. Likewise, the opposite electrode 223 and the capping layer 230 may also be disconnected or separated by the sub-grooves SG.

In such embodiments, by disposing the inorganic stack including the lower metal layer 250, the first interlayer insulating layer 205, the first metal layer 260, the second interlayer insulating layer 207, and the second metal layer 270 under the groove G, the thickness of the first organic insulating layer 209 to be etched to form an undercut structure of the tip PT and the groove G may be controlled. Because the first organic insulating layer 209 may be removed from the upper surface of the first organic insulating layer 209 to the upper surface of the second metal layer 270 to form the tip PT and the groove G, the process control may be easy and the structural disconnection of the intermediate layer 222 may be easy and thus the reliability thereof may be improved. Also, as the size of the grooves G is reduced, the spacing distance between the tips PT may be reduced and thus more grooves G may be additionally arranged in a same area. In a comparative example, where the inorganic stack structure is not provided under the groove, particles may be generated and the layer located under the groove may be damaged due to over-etching of the first organic insulating layer.

In an embodiment, as shown in FIG. 6, a partition wall PW may be formed in the intermediate area MA before the intermediate layer 222 is formed. The partition wall PW may include a plurality of organic layers stacked over the first organic insulating layer 209. However, a portion of the first organic insulating layer 209 may also form the partition wall PW. The plurality of organic layers may respectively correspond to a portion of the second organic insulating layer 211, a portion of the pixel definition layer 215, and a portion of the spacer 217. One or more layers among the plurality of organic layers may be omitted or added. FIG. 6 illustrates an embodiment where a single partition wall PW is located in the intermediate area MA; however, in some embodiments, two or more partition walls PW may be located in the intermediate area MA.

The thin film encapsulation layer 300 may be disposed over the capping layer 230. The first inorganic encapsulation layer 310 and the second inorganic encapsulation layer 330 may be formed by chemical vapor deposition. Because the first inorganic encapsulation layer 310 has relatively high step coverage, the first inorganic encapsulation layer 310 may be continuously formed to cover the inner surface and bottom surface of the groove G. For example, the first inorganic encapsulation layer 310 may extend while covering the upper, side, and lower surfaces of the tip PT and thus may cover the organic material layers separated from the intermediate layer 222 located on the side surface of the first organic insulating layer 209 and the upper surface of the second metal layer 270 that define the groove G.

The organic encapsulation layer 320 may be arranged between the first inorganic encapsulation layer 310 and the second inorganic encapsulation layer 330, and the end of the organic encapsulation layer 320 may be arranged adjacent to one side of the partition wall PW between adjacent grooves G. The inner space of some of the grooves G, for example, the second groove 2G adjacent to the display area DA, may be at least partially filled by the organic encapsulation layer 320.

Similarly to the first inorganic encapsulation layer 310, the second inorganic encapsulation layer 330 may have relatively high step coverage. Thus, the second inorganic encapsulation layer 330 may be continuously formed along the side surface and bottom surface of the first groove 1G not covered by the organic encapsulation layer 320 among the grooves G.

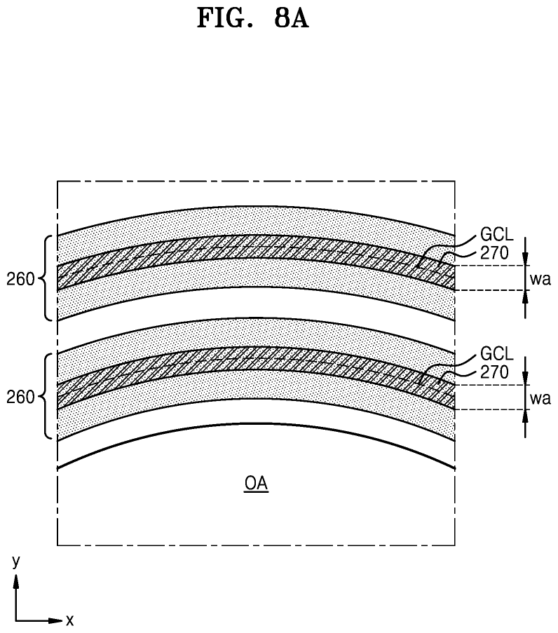

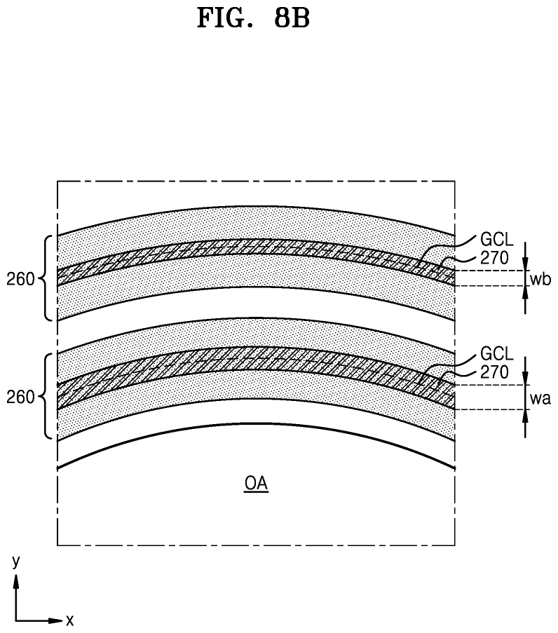

FIGS. 8A and 8B are plan views schematically illustrating a portion of a display panel according to embodiments. For convenience of illustration and description, FIGS. 8A and 8B selectively illustrate the first metal layer 260 and the second metal layer 270 included in the inorganic stack.

Referring to FIGS. 8A and 8B, in embodiments, one or more grooves may be arranged around the opening area OA. FIGS. 8A and 8B illustrate imaginary center lines GCL passing through the center of each groove. In an embodiment, as shown in FIGS. 8A and 8B, two imaginary center lines GCL may extend to surround the opening area OA and may have a concentric circle shape having different diameters.

First metal layers 260 may be arranged along the imaginary center line GCL to overlap the imaginary center line GCL. The first metal layers 260 may have a closed loop shape surrounding the opening area OA.

Second metal layers 270 may be arranged to overlap the first metal layer 260 and the imaginary center line GCL. The second metal layers 270 may have a closed loop shape surrounding the opening area OA. Each of the second metal layers 270 may have a smaller width than the first metal layer 260 corresponding thereto.

In some embodiments, the second metal layers 270 may have a same width as each other. For example, the second metal layer 270 arranged relatively adjacent to the opening area OA and the second metal layer 270 arranged relatively far from the opening area OA may have a fifth width wa.

In some other embodiments, the second metal layers 270 may have different widths. For example, FIG. 8B illustrates an embodiment where the second metal layer 270 arranged relatively adjacent to the opening area OA has a fifth width wa and the second metal layer 270 arranged relatively far from the opening area OA has a sixth width wb less than the fifth width wa. Alternatively, the second metal layer 270 arranged relatively adjacent to the opening area OA has a sixth width wb and the second metal layer 270 arranged relatively far from the opening area OA has a fifth width wa greater than the sixth width wb.

As described above with reference to FIG. 7A, the fifth width wa may be greater than the first distance d1 between the tips PT and the first width w1 of the groove G. As described above with reference to FIG. 7B, the sixth width wb may be greater than the first distance d1 between the tips PT but may be less than the first width w1 of the groove G. In this case, at least a portion of the upper surface and side surface of the second metal layer 270 having the sixth width wb may be exposed from a first organic insulating layer through a groove. The groove may include sub-grooves SG (see FIG. 7B) defined on opposing sides of the second metal layer 270.

In some embodiments, all of the second metal layers 270 may have the same sixth width wb. In this case, each of the grooves may include sub-grooves SG (see FIG. 7B) defined on opposing sides of the second metal layer 270.

FIGS. 8A and 8B illustrate embodiments where two grooves are provided; however, the display panel may include three or more grooves.

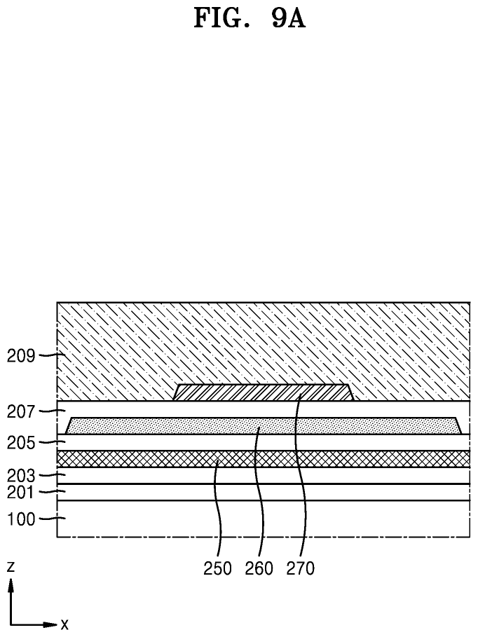

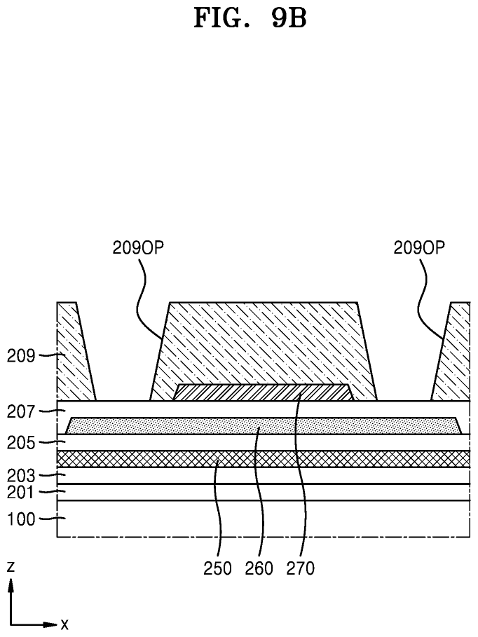

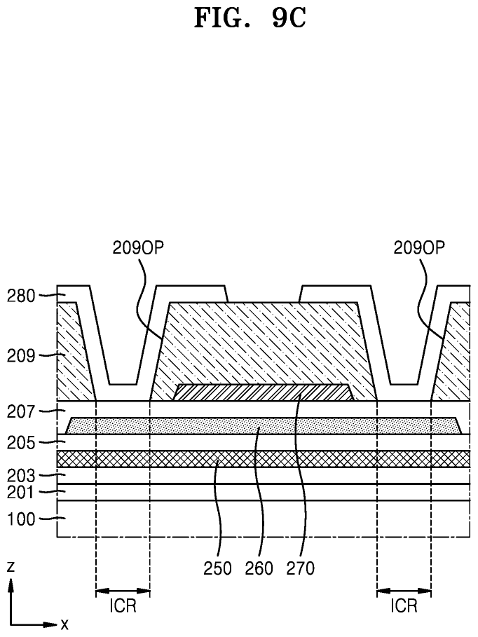

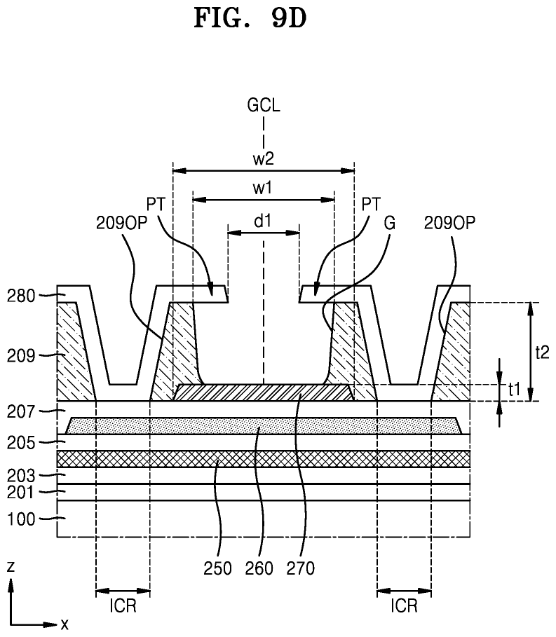

FIGS. 9A to 9D are cross-sectional views schematically illustrating cross-sections of a display panel during a manufacturing process according to an embodiment.

Referring to FIG. 9A, an inorganic stack and a first organic insulating layer 209 may be formed over a substrate 100. The inorganic stack may include an inorganic insulating layer and/or a metal layer. In an embodiment, as shown in FIG. 9A, the inorganic stack includes a lower metal layer 250, a first interlayer insulating layer 205, a first metal layer 260, a second interlayer insulating layer 207, and a second metal layer 270.

The lower metal layer 250 may be formed in a same process as the gate electrode GE of the thin film transistor TFT and the lower electrode CE1 of the storage capacitor Cst described above with reference to FIG. 6. The first metal layer 260 may be formed in a same process as the upper electrode CE2 of the storage capacitor Cst. The second metal layer 270 may be formed in a same process as the source electrode SE and/or the drain electrode DE.

A first organic insulating layer 209 may be formed over the inorganic stack.

Referring to FIG. 9B, first openings 209OP may be formed or defined in the first organic insulating layer 209. In the plan view, the first opening 209OP may overlap the lower metal layer 250 and the first metal layer 260 but may not overlap the second metal layer 270. That is, the first opening 209OP may be arranged apart from the second metal layer 270. The first opening 209OP may pass through the first organic insulating layer 209 to expose the upper surface of the second interlayer insulating layer 207. A plurality of first openings 209OP may be provided and arranged on opposing sides of the second metal layer 270.

Referring to FIG. 9C, a third metal layer 280 may be formed over the first organic insulating layer 209. The third metal layer 280 may be formed in a same process as the contact metal layer CM (see FIG. 6). The third metal layer 280 may directly contact the upper surface of the second interlayer insulating layer 207 through the first opening 209OP to form an inorganic contact area ICR.

A plurality of third metal layers 280 may be provided and may be arranged apart from each other. An opening portion defined between adjacent third metal layers 280 may overlap the second metal layer 270 in the plan view.

Referring to FIG. 9D, a groove G may be formed by etching a portion of the first organic insulating layer 209 by using the third metal layer 280 as a mask. The upper surface of the second metal layer 270 may function as an etch stopper in an etching process of forming the groove G. The groove G may include a side surface and a bottom surface, the side surface of the groove G may be the side surface of the first organic insulating layer 209, and the bottom surface of the groove G may be the upper surface of the second metal layer 270. Because the groove G is formed only from the upper surface of the first organic insulating layer 209 to the upper surface of the second metal layer 270, the etching process may be easily controlled.

In some embodiments, as illustrated in FIG. 9D, where the groove G has a first width w1 from one side surface to the other side surface thereof, the second metal layer 270 may have a second width w2 greater than the first width w1. In some other embodiments, the second metal layer 270 may have a fourth width w4 less than the first width w1.

As a portion of the first organic insulating layer 209 located under the third metal layer 280 is removed, the third metal layer 280 may form a tip PT protruding in the direction of an imaginary center line GCL passing through the center of the groove G. A first distance d1 between the tips PT arranged facing each other with the groove G therebetween may be less than the second width w2 of the second metal layer 270.

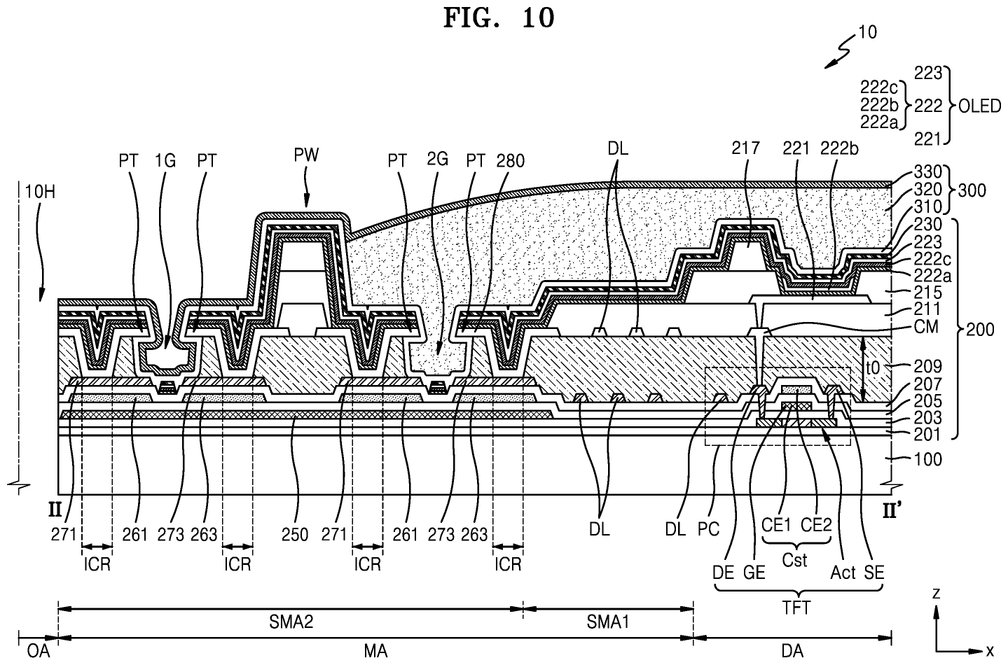

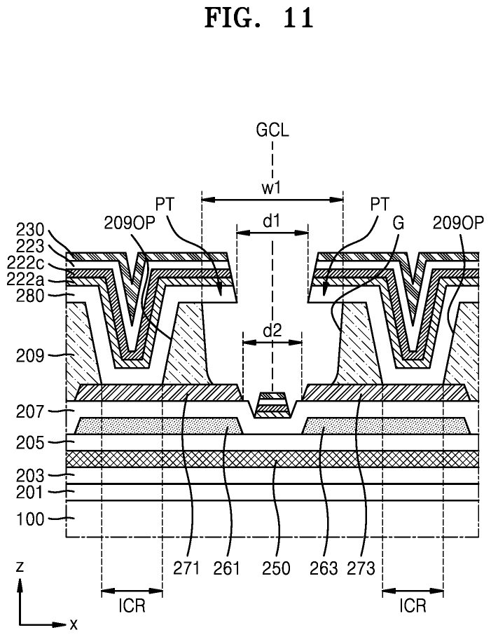

FIG. 10 is a cross-sectional view schematically illustrating a display panel according to an embodiment, and FIG. 11 is a cross-sectional view schematically illustrating a groove in a display panel according to an embodiment.

FIG. 10 is similar to FIG. 6 but is different therefrom in terms of the configuration of sub-layers constituting an inorganic stack. Hereinafter, any repetitive detailed descriptions of the same or similar configurations as those described above will be omitted or simplified and differences therebetween will be mainly described.

Referring to FIGS. 10, 11, and 12, in the second sub-intermediate area SMA2, an inorganic stack may be located between the first organic insulating layer 209 and the substrate 100. The inorganic stack may include a plurality of sub-layers, and the sub-layers may include an inorganic material. For example, the inorganic stack may include at least one inorganic insulating layer and at least one metal layer.

In the second sub-intermediate area SMA2, the inorganic stack may be arranged on opposing sides of each of the grooves 1G and 2G. The lower metal layer 250 may be integrally provided across a plurality of grooves 1G and 2G. A first inorganic stack located inside with respect to the imaginary center line GCL passing through the center of the groove G may include a lower metal layer 250, a first interlayer insulating layer 205, a first sub-metal layer 261, a second interlayer insulating layer 207, and a second sub-metal layer 271. A second inorganic stack located outside with respect to the virtual center line GCL may include a lower metal layer 250, a first interlayer insulating layer 205, a third sub-metal layer 263, a second interlayer insulating layer 207, and a fourth sub-metal layer 273.

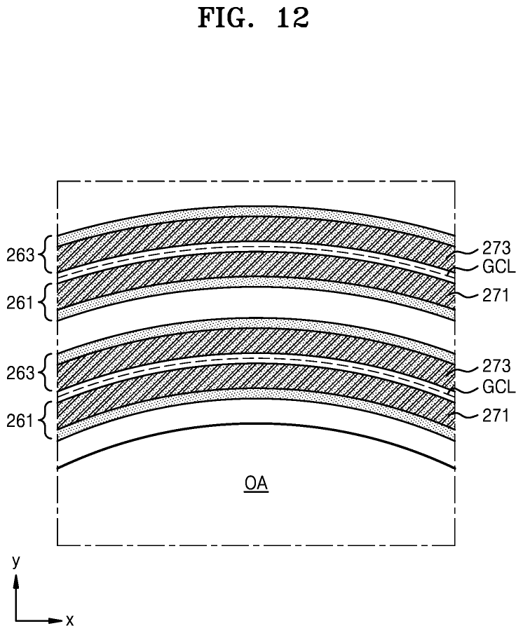

The first sub-metal layer 261 and the third sub-metal layer 263 may be arranged apart from each other and disposed in a same layer with the imaginary center line GCL therebetween. The second sub-metal layer 271 and the fourth sub-metal layer 273 may be arranged apart from each other and disposed in a same layer with the imaginary center line GCL. That is, as illustrated in FIG. 12, in the plan view, the first sub-metal layer 261, the third sub-metal layer 263, the second sub-metal layer 271, and the fourth sub-metal layer 273 may not overlap the imaginary center line GCL.

In some embodiments, the second sub-metal layer 271 and the fourth sub-metal layer 273 may be arranged apart from each other by a second distance d2 with the center portion of the groove G therebetween. A first width w1 of the groove G may be greater than the second distance d2. Thus, a portion and one side of the upper surface of the second sub-metal layer 271 and a portion and one side of the upper surface of the fourth sub-metal layer 273 may be exposed from the first organic insulating layer 209 through the first opening 209OP.

The first sub-metal layer 261 and the third sub-metal layer 263 may be disposed over the first interlayer insulating layer 205, may be formed in a same process as the upper electrode CE2 of the storage capacitor Cst, and may include a same material as the electrode CE2. The second sub-metal layer 271 and the fourth sub-metal layer 273 may be disposed over the second interlayer insulating layer 207, may be formed in a same process as the source electrode SE and/or the drain electrode DE of the pixel circuit PC, and may include a same materials as the source electrode SE and/or the drain electrode DE.

The inorganic insulating layer included in the inorganic stack, for example, the first interlayer insulating layer 205 and the second interlayer insulating layer 207, may include silicon nitride and/or silicon oxide. Compared to silicon oxynitride, silicon nitride and silicon oxide may be relatively resistant to moisture and may be relatively resistant to oxidation even when exposed to moisture.

The groove G may overlap a portion of the second sub-metal layer 271 and a portion of the fourth sub-metal layer 273 in the plan view. The groove G may be defined by the first organic insulating layer 209, a portion of the second sub-metal layer 271, a portion of the fourth sub-metal layer 273, and the second interlayer insulating layer 207. In other words, the groove G may be defined by the side surface of the first organic insulating layer 209, the upper and side surfaces of the second sub-metal layer 271 exposed from the first organic insulating layer 209, the upper and side surfaces of the fourth sub-metal layer 273 exposed from the first organic insulating layer 209, and the upper and side surfaces of the second interlayer insulating layer 207 exposed between the second sub-metal layer 271 and the fourth sub-metal layer 273.

The first organic insulating layer 209 may define first openings 209OP arranged apart from each other on opposing sides of the groove G. In the plan view, the first openings 209OP may respectively overlap the second sub-metal layer 271 and the fourth sub-metal layer 273.

Third metal layers 280 may be arranged on opposing sides of the groove G over the first organic insulating layer 209. The third metal layer 280 may be formed in a same process as the contact metal layer CM and may include a same material as the contact metal layer CM.

The third metal layer 280 may directly contact the upper surface of the second sub-metal layer 271 or the fourth sub-metal layer 273 through the first opening 209OP to form an inorganic contact area ICR.

The third metal layer 280 may extend from the upper surface of the first organic insulating layer 209 and may include a tip PT protruding from the side surface of the first organic insulating layer 209 in the direction of the imaginary center line GCL passing through the center of the groove G. Tips PT arranged facing each other with the groove G therebetween may be spaced apart from each other by a first distance d1. The first distance d1 between the tips PT may be greater than a second distance d2 between the second sub-metal layer 271 and the fourth sub-metal layer 273. In the plan view, the end of each of the tips PT may overlap the second sub-metal layer 271 or the fourth sub-metal layer 273. In other words, the second sub-metal layer 271 and the fourth sub-metal layer 273 may be arranged extending more toward the center of the groove G than the ends of the tips PT.

As the first openings 209OP are arranged respectively overlapping the second sub-metal layer 271 and the fourth sub-metal layer 273, it may be easier to control the height from the upper surface of the second sub-metal layer 271 to the lower surface of the third metal layer 280. Also, as a step is formed on the bottom surface of the groove G due to the interval between the second sub-metal layer 271 and the fourth sub-metal layer 273 and the interval between the first sub-metal layer 261 and the third sub-metal layer 263, the length of a path through which moisture or the like penetrates along the organic material layer from the boundary of the panel hole 10H may be extended and thus moisture penetration or the like may be effectively delayed.

FIG. 12 is a plan view schematically illustrating a portion of a display panel according to an embodiment.

Referring to FIG. 12, one or more grooves may be arranged around the opening area OA. FIG. 12 illustrates imaginary center lines GCL passing through the center of each groove. The virtual center lines GCL may extend to surround the opening area OA and may have the shape of concentric circles having a same center but having different diameters from each other.

The first sub-metal layer 261 and the third sub-metal layer 263 may be arranged apart from each other around each imaginary center line GCL. That is, in the plan view, the first sub-metal layer 261 and the third sub-metal layer 263 may not overlap the imaginary center line GCL.

The first sub-metal layer 261 and the third sub-metal layer 263 may have a closed loop shape surrounding the open area OA. The first sub-metal layer 261 and the third sub-metal layer 263 may have the shape of concentric circles having a same center but having different diameters from each other.

The second sub-metal layer 271 and the fourth sub-metal layer 273 may be arranged apart from each other around each imaginary center line GCL. In the plan view, the second sub-metal layer 271 may be arranged to overlap the first sub-metal layer 261, and the fourth sub-metal layer 273 may be arranged to overlap the third sub-metal layer 263. The width of the second sub-metal layer 271 may be less than the width of the first sub-metal layer 261. The width of the fourth sub-metal layer 273 may be less than the width of the third sub-metal layer 263.

The second sub-metal layer 271 and the fourth sub-metal layer 273 may have a closed loop shape surrounding the open area OA. The second sub-metal layer 271 and the fourth sub-metal layer 273 may have the shape of concentric circles having a same center but having different diameters from each other.

In some embodiments, the spacing distance between the second sub-metal layer 271 and the fourth sub-metal layer 273 may be substantially equal to the spacing distance between the first sub-metal layer 261 and the third sub-metal layer 263. In some other embodiments, the spacing distance between the second sub-metal layer 271 and the fourth sub-metal layer 273 may be different from the spacing distance between the first sub-metal layer 261 and the third sub-metal layer 263.

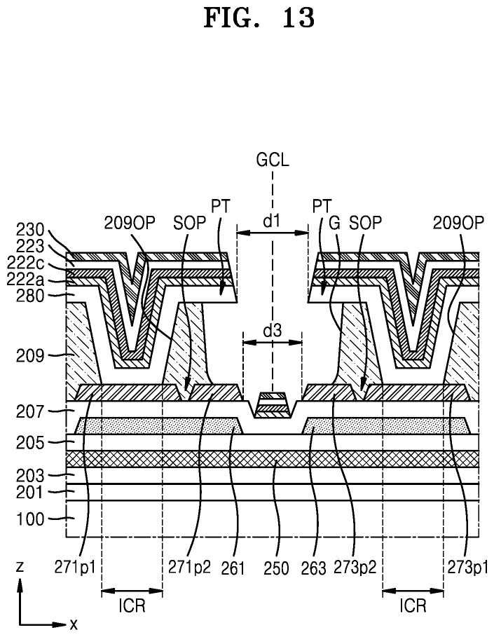

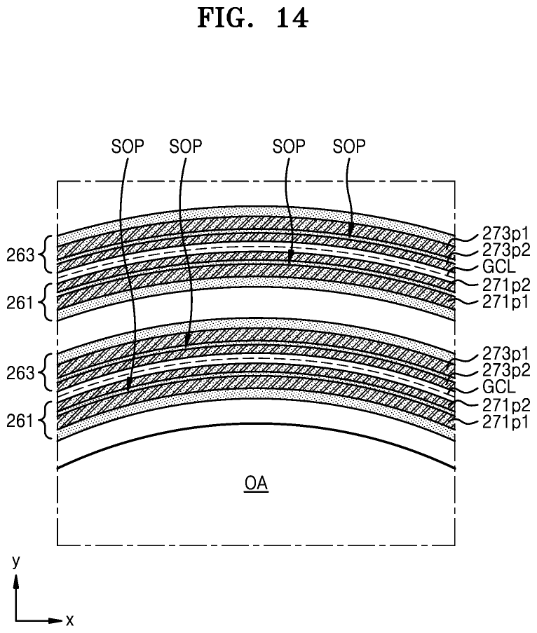

FIG. 13 is a cross-sectional view schematically illustrating a groove in a display panel according to an embodiment, and FIG. 14 is a plan view schematically illustrating a portion of a display panel according to an embodiment. FIGS. 13 and 14 are respectively similar to FIGS. 10 and 12 but are respectively different therefrom in that each of the second sub-metal layer 271 and the fourth sub-metal layer 273 is separated into a first portion and a second portion by a sub-opening SOP.

Referring to FIGS. 13 and 14, the second sub-metal layer 271 may include a first portion 271p1 and a second portion 271p2 separated by a sub-opening SOP, and the fourth sub-metal layer 273 may include a first portion 273p1 and a second portion 273p2 separated by a sub-opening SOP.

The sub-opening SOP may be located between the groove G and the first opening 209OP. The first portion 271p1 of the second sub-metal layer 271 and the first portion 273p1 of the fourth sub-metal layer 273 may be located relatively far from the groove G. The second portion 271p2 of the second sub-metal layer 271 and the second portion 273p2 of the fourth sub-metal layer 273 may be located relatively close to the groove G.

The end of each of the tips PT of the third metal layer 280 may overlap the second portion 271p2 of the second sub-metal layer 271 or the second portion 273p2 of the fourth sub-metal layer 273 in the plan view.

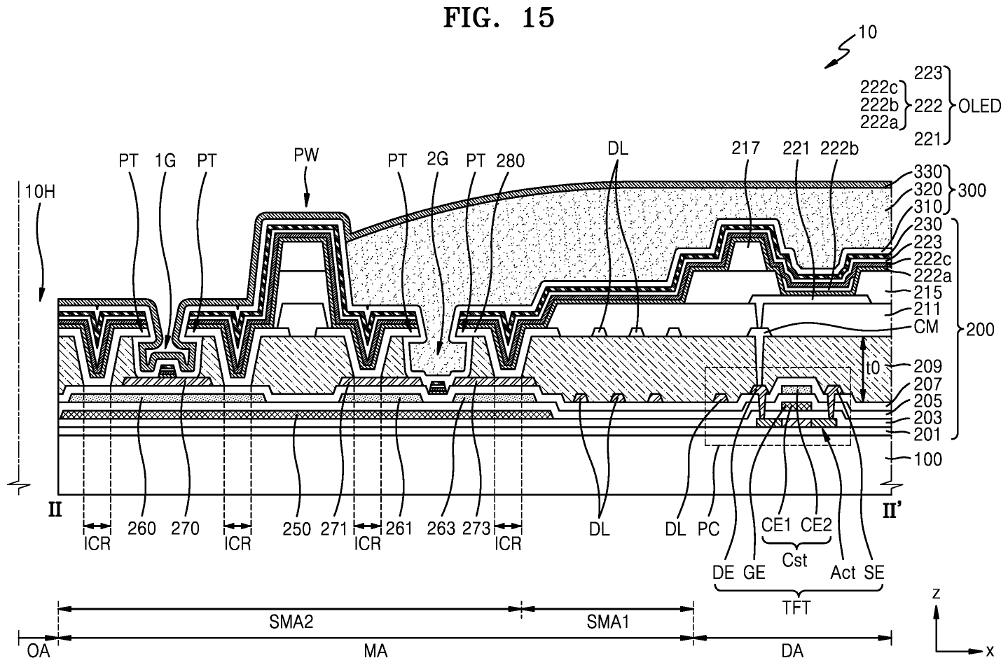

FIG. 15 is a cross-sectional view schematically illustrating a display panel according to an embodiment. FIG. 15 is similar to FIG. 6 but is different therefrom in terms of the configuration of the second groove 2G and the sub-layers constituting an inorganic stack under the second groove 2G. Hereinafter, any repetitive detailed descriptions of the same or similar configurations as those described above will be omitted or simplified and differences therebetween will be mainly described.

Referring to FIG. 15, in the second sub-intermediate area SMA2, an inorganic stack may be located between the first organic insulating layer 209 and the substrate 100. The inorganic stack may be arranged corresponding to each of the grooves 1G and 2G.

The inorganic stack corresponding to the first groove 1G may include a lower metal layer 250, a first interlayer insulating layer 205, a first metal layer 260, a second interlayer insulating layer 207, and a second metal layer 270. The inorganic stack corresponding to the second groove 2G may include a lower metal layer 250, a first interlayer insulating layer 205, a first sub-metal layer 261, a third sub-metal layer 263, a second interlayer insulating layer 207, a second sub-metal layer 271, and a fourth sub-metal layer 273.

The lower metal layer 250 may be integrally or commonly provided across a plurality of grooves 1G and 2G.

The first metal layer 260 and the second metal layer 270 may be arranged overlapping the center of the first groove 1G in the plan view. The upper surface of the second metal layer 270 may form the bottom surface of the first groove 1G. In the plan view, the first sub-metal layer 261 and the third sub-metal layer 263 may overlap the second groove 2G but may be arranged apart from the center of the second groove 2G. In the plan view, the second sub-metal layer 271 and the fourth sub-metal layer 273 may overlap the second groove 2G but may be arranged apart from the center of the second groove 2G.

A plurality of third metal layers 280 may be provided, the third metal layer 280 adjacent to the first groove 1G may include a tip PT protruding in the center direction of the first groove 1G, and the third metal layer 280 (or the fourth metal layer) adjacent to the second groove 2G may include a tip PT protruding in the center direction of the second groove 2G.

The end of the tip PT protruding in the center direction of the first groove 1G may overlap the second metal layer 270 in the plan view, and the end of the tip PT protruding in the center direction of the second groove 2G may overlap the end of the second sub-metal layer 271 or the fourth sub-metal layer 273 in the plan view.

In an embodiment, as illustrated in FIG. 15, by configuring the structures of the first groove 1G and the second groove 2G differently from each other, the volume of each groove may vary or a buffer may be formed only in some area to improve space utilization.

Although only two grooves are illustrated in FIG. 15, three or more grooves may be arranged in the second sub-intermediate area SMA2. Also, the structures of the grooves may be the same or different from each other. As for the structures of the grooves, the embodiments described above with reference to FIGS. 7A, 7B, 11, and 13 and embodiments derived therefrom may be applied thereto.

In the display panel according to an embodiment described above, penetration of moisture or the like from the opening area along the organic material layer into the display area may be effectively prevented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel comprising:
a substrate comprising a display area and an intermediate area, wherein the display area surrounds a through hole of the display panel and the intermediate area is between the through hole and the display area;
an organic insulating layer disposed over the substrate and defining a groove in the intermediate area;
a first metal layer disposed under the organic insulating layer;
a second metal layer disposed between the first metal layer and the organic insulating layer and overlapping the first metal layer and the groove; and
a third metal layer disposed over the organic insulating layer and comprising a tip protruding from a side surface of the groove to a center of the groove.

2. The display panel of claim 1, wherein an end of the tip overlaps the second metal layer in a plan view.

3. The display panel of claim 1, further comprising:
an inorganic insulating layer disposed between the first metal layer and the second metal layer,
wherein the organic insulating layer defines a first opening located in the intermediate area and spaced apart from the second metal layer in a plan view, and
the third metal layer directly contacts the inorganic insulating layer through the first opening.

4. The display panel of claim 3, wherein the first opening overlaps the first metal layer in a plan view.

5. The display panel of claim 1, wherein a width of the second metal layer is greater than a width of the groove.

6. The display panel of claim 1, wherein a width of the second metal layer is less than a width of the groove.

7. The display panel of claim 6, wherein an upper surface of the second metal layer and at least a portion of a side surface of the second metal layer is exposed from the organic insulating layer through the groove.

8. The display panel of claim 6, wherein the groove comprises a sub-groove defined by a side surface of the groove, a bottom surface of the groove, and a side surface of the second metal layer.

9. The display panel of claim 1, wherein the groove comprises a first groove and a second groove,
a width of the second metal layer corresponding to the first groove is less than a width of the first groove, and
a width of the second metal layer corresponding to the second groove is greater than a width of the second groove.

10. The display panel of claim 1, further comprising:
a light emitting diode disposed in the display area and comprising a pixel electrode, an opposite electrode, and an intermediate layer disposed between the pixel electrode and the opposite electrode,
wherein the intermediate layer extends from the display area to the intermediate area and is disconnected by the groove.

11. A display panel comprising:
a substrate comprising a display area and an intermediate area, wherein the display area surrounds a through hole of the display panel and the intermediate area is between the through hole and the display area;
an organic insulating layer disposed over the substrate and defining a groove in the intermediate area;
a first sub-metal layer disposed under the organic insulating layer, overlapping the groove, and spaced apart from a center of the groove;
a second sub-metal layer disposed between the first sub-metal layer and the organic insulating layer, overlapping the groove and the first sub-metal layer, and spaced apart from the center of the groove in a plan view; and
a third metal layer disposed over the organic insulating layer and comprising a tip protruding from a side surface of the groove to the center of the groove,
wherein an end of the tip overlaps the second sub-metal layer in the plan view.

12. The display panel of claim 11, wherein the organic insulating layer defines a first opening located in the intermediate area and overlapping the second sub-metal layer, and
the third metal layer directly contacts the second sub-metal layer through the first opening.

13. The display panel of claim 12, wherein the second sub-metal layer defines a sub-opening between the groove and the first opening in the plan view, and
the sub-opening separates the second sub-metal layer into a first portion and a second portion.

14. The display panel of claim 13, wherein the first portion of the second sub-metal layer overlaps the first opening in the plan view, and the second portion of the second sub-metal layer overlaps the groove in the plan view.

15. The display panel of claim 11, further comprising:
a third sub-metal layer disposed in a same layer as the first sub-metal layer and apart from the first sub-metal layer with the center of the groove therebetween; and
a fourth sub-metal layer disposed in a same layer as the second sub-metal layer and apart from the second sub-metal layer with the center of the groove therebetween.

16. The display panel of claim 15, wherein a spacing distance between the second sub-metal layer and the fourth sub-metal layer is less than a width of the groove.

17. The display panel of claim 11, wherein an upper surface of the second sub-metal layer and at least a portion of a side surface of the second sub-metal layer is exposed from the organic insulating layer through the groove.

18. The display panel of claim 11, further comprising:
a light emitting diode disposed in the display area and comprising a pixel electrode, an opposite electrode, and an intermediate layer disposed between the pixel electrode and the opposite electrode,
wherein the intermediate layer extends from the display area to the intermediate area and is disconnected by the groove.

19. A display panel comprising:
a substrate comprising a display area surrounding a through hole of the display panel and an intermediate area between the through hole and the display area;
an organic insulating layer disposed over the substrate and defining a first groove and a second groove located in the intermediate area;
a first metal layer disposed under the organic insulating layer and overlapping the first groove;
a first sub-metal layer disposed under the organic insulating layer, overlapping the second groove, and spaced apart from a center of the second groove in a plan view;
a second metal layer disposed between the first metal layer and the organic insulating layer and overlapping the first metal layer and the first groove;
a second sub-metal layer disposed between the first sub-metal layer and the organic insulating layer, overlapping the first sub-metal layer, and spaced apart from the center of the second groove in the plan view;
a third metal layer disposed over the organic insulating layer and comprising a first tip protruding from a side surface of the first groove to a center of the first groove; and
a fourth metal layer disposed over the organic insulating layer and comprising a second tip protruding from a side surface of the second groove to the center of the second groove.

20. The display panel of claim 19, wherein an end of the first tip overlaps the second metal layer in the plan view, and
an end of the second tip overlaps the second sub-metal layer in the plan view.
